(19) United States
(12) Patent Application Publication
(10) Pub. No.: US 2022/0293399 A1
(43) Pub. Date: Sep. 15, 2022

(54) SUBSTRATE PROCESSING APPARATUS AND METHOD OF CONTROLLING THE SAME

(71) Applicant: TOKYO ELECTRON LIMITED, Tokyo (JP)

(72) Inventor: Kiyoshi MORI, Tokyo (JP)

(21) Appl. No.: 17/689,659

(22) Filed: Mar. 8, 2022

(30) Foreign Application Priority Data
Mar. 12, 2021 (JP) 2021-040513

(51) Int. Cl. H01J 37/32

(52) U.S. Cl. CPC H01J 37/32715; H01J 37/32899; H01J 2237/20214

(57) ABSTRACT

A substrate processing apparatus includes: a processing container having a plurality of processing spaces formed therein; a substrate stage arranged in each of the plurality of processing spaces; a rotary arm including at least one end effector capable of holding a substrate and having a rotation axis located at a position equidistant from the plurality of processing spaces; a sensor provided on a back surface of the at least one end effector of the rotary arm, which is opposite to a substrate holding surface of the at least one end effector; and a rotation mechanism configured to rotate the rotary arm so that the sensor is moved to a position facing the substrate stage or the substrate placed on the substrate stage inside the processing container.

### CROSS-REFERENCE TO RELATED APPLICATION

This application is based upon and claims the benefit of priority from Japanese Patent Application No. 2021-040513, filed on Mar. 12, 2021, the entire contents of which are incorporated herein by reference.

### TECHNICAL FIELD

The present disclosure relates to a substrate processing apparatus and a method of controlling the substrate processing apparatus.

### BACKGROUND

In a polishing apparatus, it has been proposed to install an in-line monitor outside a processing space for polishing a substrate, transfer the polished substrate to the outside of the processing space, and measure the film thickness of the substrate or the like by the in-line monitor (Patent Document 1). Further, as a substrate processing apparatus for processing a substrate (hereinafter also referred to as a wafer) in a substrate processing system, there is known a substrate processing apparatus in which a plurality of wafers is simultaneously processed in one processing container (Patent Document 2).

### PRIOR ART DOCUMENT

### Patent Document

Patent Document 1: Japanese Laid-Open Patent Publication No. 2006-043873
Patent Document 2: Japanese Laid-Open Patent Publication No. 2019-220509

### SUMMARY

According to one embodiment of the present disclosure, there is provided a substrate processing apparatus includes: a processing container having a plurality of processing spaces formed therein; a substrate stage arranged in each of the plurality of processing spaces; a rotary arm including at least one end effector capable of holding a substrate and having a rotation axis located at a position equidistant from the plurality of processing spaces; a sensor provided on a back surface of the at least one end effector of the rotary arm, which is opposite to a substrate holding surface of the at least one end effector; and a rotation mechanism configured to rotate the rotary arm so that the sensor is moved to a position facing the substrate stage or the substrate placed on the substrate stage inside the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an exploded perspective view showing an example of a configuration of a substrate processing apparatus according to an embodiment of the present disclosure.

FIG. 2 is a diagram showing an example of a positional relationship between processing spaces and a rotary arm at a standby position.

FIG. 3 is a diagram showing an example of a positional relationship between the processing spaces and the rotary arm at a wafer holding position.

FIG. 4 is a diagram showing an example of a movement path of a wafer in the substrate processing apparatus according to the present embodiment.

FIG. 5 is a diagram showing an example of an exhaust path of the substrate processing apparatus according to the present embodiment.

FIG. 6 is a schematic sectional view showing an example of a configuration of the substrate processing apparatus according to the present embodiment.

FIG. 7 is a perspective view showing an example of a configuration of the rotary arm shown in FIG. 6 when viewed from a back surface of an end effector.

FIG. 8 is a diagram showing an example of an operation of the substrate processing apparatus.

FIG. 9 is a diagram for explaining an example of a sensor in a modification.

### DETAILED DESCRIPTION

Hereinafter, embodiments of a substrate processing apparatus and a method of controlling the substrate processing apparatus disclosed herein will be described in detail with reference to the drawings. The disclosed techniques are not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a substrate processing apparatus in which a plurality of wafers is processed simultaneously in one processing container, a rotary arm capable of holding the wafers may be provided at the center of the processing container in order to transfer the wafers between the respective processing spaces. In the configuration in which the rotary arm is provided at the central portion of the processing container, no consideration is given to various measurements regarding a substrate stage or the substrate placed on the substrate stage inside the processing container. Therefore, it is expected to perform various measurements on the substrate stage or the substrate placed on the substrate stage in the processing container.

### [Configuration of Substrate Processing Apparatus]

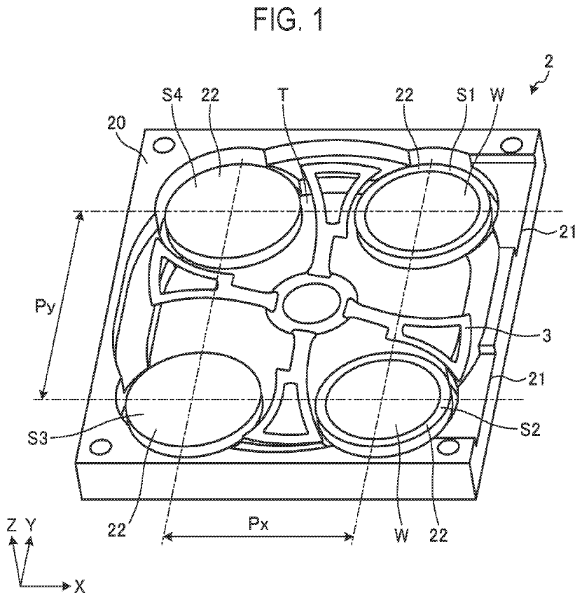

FIG. 1 is an exploded perspective view showing an example of a configuration of a substrate processing apparatus according to an embodiment of the present disclosure. In the present embodiment, an example in which a substrate processing apparatus 2 shown in FIG. 1 is applied to a film-forming apparatus that performs a plasma CVD (Chemical Vapor Deposition) process on a wafer W will be described. As shown in FIG. 1, the substrate processing apparatus 2 includes a processing container (vacuum container) 20 having a rectangular shape in a plan view. The processing container 20 is configured so that the interior thereof can be maintained in a vacuum atmosphere. The processing container 20 is configured by closing an open portion on the upper surface with a gas supplier 4 and a manifold 36 described later. In FIG. 1, an internal partition wall and the like are omitted so that the relationship between a plurality of processing spaces S1 to S4 and a rotary arm 3 can be easily understood. Two loading/unloading ports 21 are formed on the side surface of the processing container 20 on the side connected to a vacuum transfer chamber (not shown) so as to be arranged side by side in the Y direction. The loading/unloading ports 21 are opened and closed by gate valves (not shown).

The plurality of processing spaces S1 to S4 are provided inside the processing container 20. A stage 22 is arranged in each of the processing spaces S1 to S4. The stage 22 is an example of a substrate stage and is movable in the vertical direction. The stage 22 is moved up when processing wafers W and is moved down when transferring the wafers W. Under the processing spaces S1 to S4, there is provided a transfer space T through which the processing spaces S1 to S4 are connected and in which the wafers W are transferred by the rotary arm 3. Further, the transfer space T under the processing spaces S1 and S2 is connected to the respective loading/unloading ports 21. The wafers W are loaded and unloaded between the transfer space T and the vacuum transfer chamber by a substrate transfer mechanism (not shown). The substrate transfer mechanism is configured to collectively deliver two wafers W to the substrate processing apparatus 2, and the substrate holding portion of the substrate transfer mechanism is configured to hold, for example, two wafers W at the same time.

The respective stages 22 of the processing spaces S1 to S4 are laid out in two-row/two-column when viewed from above. The layout has different dimensions for row spacing and column spacing. That is, when the pitch Py as a Y-direction pitch (row spacing) of the stage 22 and the pitch Px as an X-direction pitch (column spacing) are compared, a relationship of pitch Py>pitch Px is set.

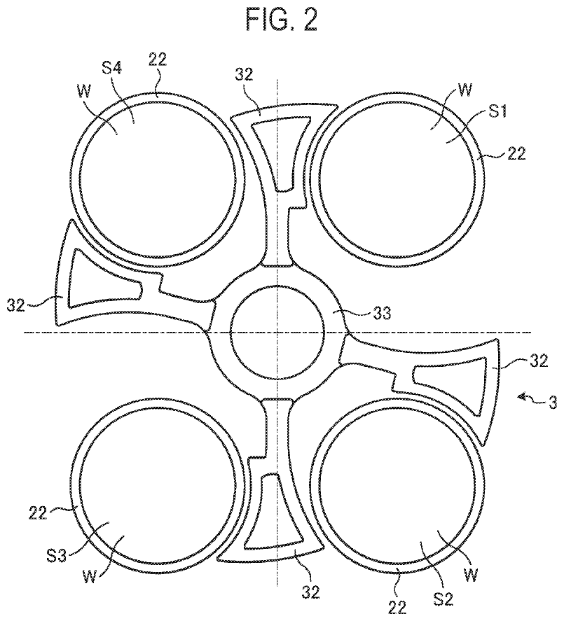

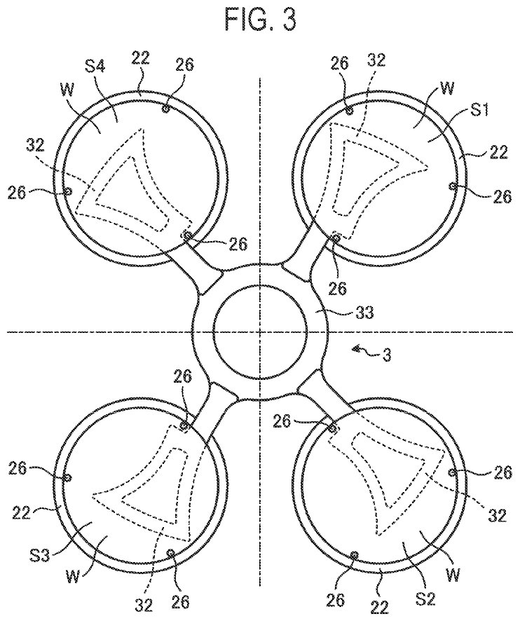

FIG. 2 is a diagram showing an example of the positional relationship between the processing spaces and the rotary arm at a standby position. FIG. 3 is a diagram showing an example of the positional relationship between the processing spaces and the rotary arm at a wafer holding position. As shown in FIGS. 2 and 3, the rotary arm 3 includes four end effectors 32 capable of holding the wafers W placed on each of the stages 22, and a base member 33 having a rotation axis located at the center position of the two-row and two-column layout. The four end effectors 32 are connected to the base member 33 in an X shape. That is, the rotary arm 3 has the same number of end effectors 32 as the plurality of processing spaces S1 to S4. Further, the rotation axis of the base member 33, i.e., the rotation axis of the rotary arm 3, is located at a position equidistant from the respective processing spaces S1 to S4. The X shape in the rotary arm 3 has a configuration in which the dimension in the Y direction corresponding to the row spacing of the X shape and the dimension in the X direction corresponding to the column spacing of the X shape are different at the wafer holding position shown in FIG. 3.

By locating the rotary arm 3 between the processing spaces S1 to S4 at the standby position shown in FIG. 2, the rotary arm 3 does not hinder the vertical movement of each stage 22. In FIG. 2, the wafer W is placed on each stage 22. Descriptions will be made on the movement of the rotary arm 3 when the wafers W in the first row and the second row are transferred from this state so as to be replaced with each other, i.e., when the wafers W in the processing spaces S1 and S2 are transferred to the processing spaces S3 and S4 and the wafers in the processing spaces S3 and S4 are transferred to the processing spaces S1 and S2.

First, each stage 22 is moved to the delivery position in the lower transfer space T, and lift pins 26 (to be described later) provided on each stage 22 are moved up to lift the wafer W. Next, the rotary arm 3 is rotated clockwise by about 30° to insert each end effector 32 between the stage 22 and the wafer W as shown in FIG. 3. Subsequently, the lift pins 26 are moved down to place the wafer W on each end effector 32. Next, the rotary arm 3 is rotated 180° clockwise to transfer the wafer W to the holding position on each stage 22. After each stage 22 receives the wafer W by moving the lift pins 26 upward, the rotary arm 3 is rotated counterclockwise by about 30° to move to the standby position. In this way, the rotary arm 3 can transfer the wafers W in the first row and the second row so that they can be replaced with each other. As a result, for example, when different processes are repeated (e.g., a film-forming process and an annealing process are repeated) in the processing spaces S1 and S2 and the processing spaces S3 and S4, it is possible to shorten the time required for the transfer of the wafers W.

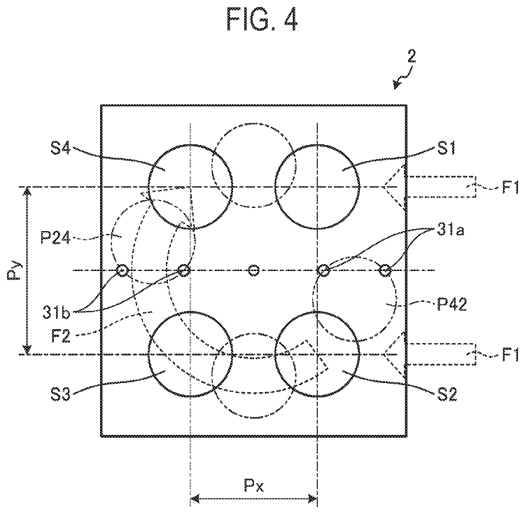

FIG. 4 is a diagram showing an example of a wafer movement path in the substrate processing apparatus according to the present embodiment. FIG. 4 shows a wafer movement path when the wafer W is transferred from a vacuum transfer chamber (not shown) to the interior of the substrate processing apparatus 2. First, by means of a substrate transfer mechanism (not shown) in the vacuum transfer chamber, as indicated by paths F1, two wafers W are simultaneously loaded to the respective stages 22 at the delivery positions in the transfer space T under the processing spaces S1 and S2 corresponding to the stages 22 in the same row. The respective stages 22 in the processing spaces S1 and S2 receive the wafers W by moving the lift pins 26 upward.

Next, the rotary arm 3 is rotated clockwise by about 30° from the standby position to insert the end effectors 32 between the stages 22 and the wafers W existing at the delivery positions under the processing spaces S1 and S2, and the lift pins 25 are moved down to place the wafers W on the end effectors 32. After the wafers W are placed, the rotary arm 3 is rotated 180° clockwise as indicated by a path F2 to transfer the wafers W onto the stages 22 (the holding positions of the rotary arm 3) existing at the delivery positions in the transfer space T under the processing spaces S3 and S4. After the stages 22 existing at the delivery positions under the processing spaces S3 and S4 receives the wafers W by moving the lift pins 26 upward, the rotary arm 3 is rotated counterclockwise by about 30° to move to the standby position. In this state, the wafers W are not placed on the stages 22 in the processing spaces S1 and S2, and the wafers W are placed on the stages 22 in the processing spaces S3 and S4. Subsequently, as indicated by paths F1, two wafers W are simultaneously loaded to the respective stages 22 existing at the delivery positions in the processing spaces S1 and S2 by the substrate transfer mechanism of the vacuum transfer chamber, and the wafers W are placed on the stages 22 in the processing spaces S1 and S2. As a result, the wafers W are placed on all the stages 22 in the processing spaces S1 to S4.

Similarly, at the time of unloading the wafers W, first, the wafers W placed on the stages 22 existing at the delivery positions under the processing spaces S1 and S2 are unloaded to the vacuum transfer chamber by the substrate transfer mechanism. Next, the wafers W placed on the stages 22 existing at the delivery positions under the processing spaces S3 and S4 are transferred to the stages 22 existing at the delivery positions under the processing spaces S1 and S2 by the rotary arm 3. Subsequently, the wafers W placed on the stages 22 existing at the delivery positions under the processing spaces S1 and S2 are unloaded to the vacuum transfer chamber by the substrate transfer mechanism. In this way, the wafers W can be loaded into and unloaded from the processing spaces S1 to S4 by the substrate transfer mechanism capable of loading and unloading two wafers W at the same time and the rotary arm 3.

Further, when the wafers W are transferred by the rotary arm 3, the misalignment of the wafer W with respect to the stage 22 at the transfer destination may be detected and may be corrected by finely moving the stage 22 in the XY plane. In this case, the substrate processing apparatus 2 includes misalignment detection sensors configured to detect a misalignment of the wafer W and respectively arranged on locus of the wafer W held by the rotary arm 3 at the rotationally symmetric positions within the row spacing or the column spacing. In the example of FIG. 4, sensors 31a and 31b are respectively provided between the processing spaces S1 and S2 and between the processing spaces S3 and S4, which are within the row spacing.

Each of the sensors 31a and 31b is, for example, a set of two optical sensors, and is arranged on a straight line in the X direction passing through the center of the substrate processing apparatus 2, i.e., the center position of the two-row and two-column layout. This is to reduce the error by allowing the expansion direction of the processing container 20 due to thermal expansion to be the same direction in the two sensors. The positions of the sensors 31a and 31b are not limited to the X direction as long as they are on a straight line passing through the center of the substrate processing apparatus 2. The substrate processing apparatus 2 detects the amount of misalignment of the wafer W by comparing the front and rear edges of the wafer W detected by the sensors 31a and 31b with the output result of an encoder (not shown) provided on the rotary arm 3.

In the example of FIG. 4, the position P24 indicates a state in which the rear edge of the wafer W has passed through the sensor 31b when the wafer W is transferred from the processing space S2 to the processing space S4, and the position P42 indicates a state in which the rear edge of the wafer W has passed through the sensor 31a when the wafer W is transferred from the processing space S4 to the processing space S2. The substrate processing apparatus 2 can correct the misalignment of the wafer W by finely moving the stage 22 in the XY plane according to the detected misalignment amount. That is, the substrate processing apparatus 2 adjusts the misalignment so that the wafer W is located at the center of each of the processing spaces S1 to S4 when the stage 22 is moved upward. The term “finely” used herein is about 5 mm or less.

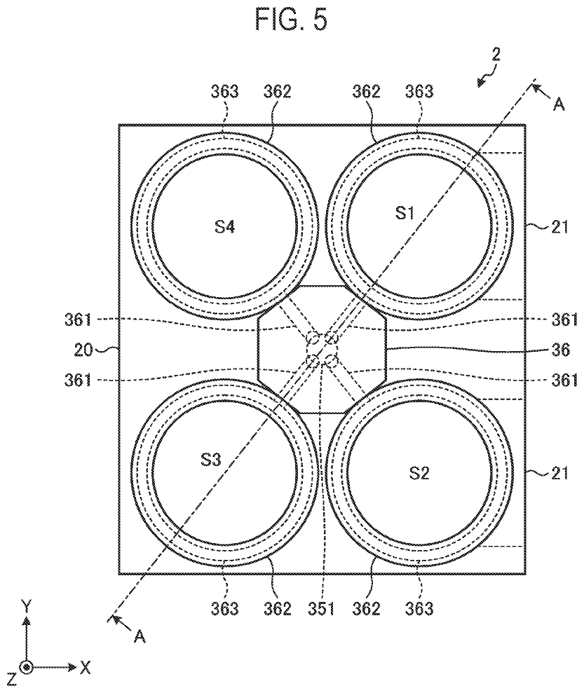

FIG. 5 is a diagram showing an example of an exhaust path of the substrate processing apparatus according to the present embodiment. FIG. 5 shows a case where the processing container 20 is viewed from above with the below-described gas supplier 4 removed. As shown in FIG. 5, a manifold 36 is arranged at the center of the substrate processing apparatus 2. The manifold 36 has a plurality of exhaust paths 361 connected to the processing spaces S1 to S4. Each exhaust path 361 is connected to a hole 351 of a thrust nut 35 (to be described later) at the lower center of the manifold 36. Each exhaust path 361 is connected to an annular flow path 363 in each guide member 362 provided in the upper portion of each of the processing spaces S1 to S4. That is, the gas in the processing spaces S1 to S4 is exhausted to a junction exhaust port 205 (to be described later) via the flow paths 363, the exhaust paths 361, and the hole 351. The manifold 36 is an example of an exhaust manifold.

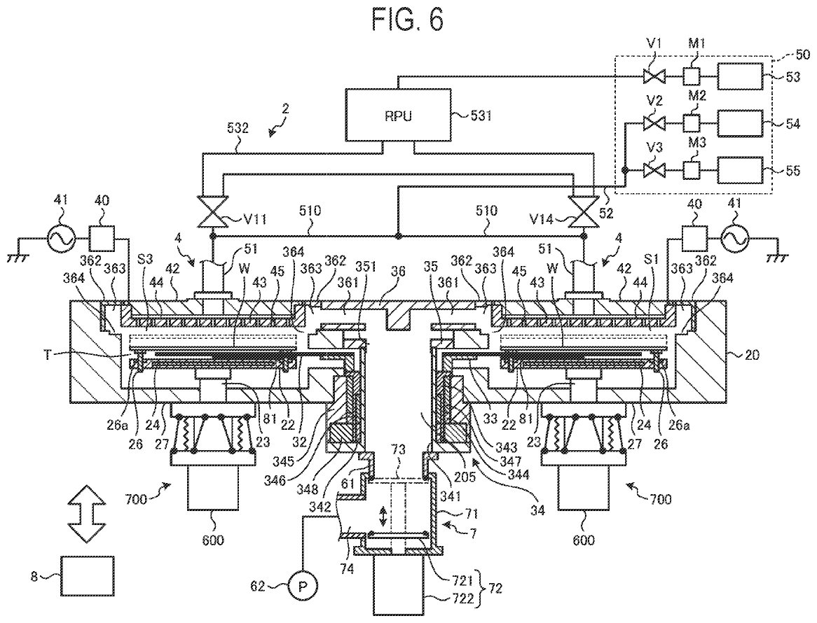

FIG. 6 is a schematic sectional view showing an example of the configuration of the substrate processing apparatus according to the present embodiment. The cross section of FIG. 6 corresponds to the cross section of the substrate processing apparatus 2 taken along line A-A in FIG. 5. The four processing spaces S1 to S4 are configured in the same manner as each other and are formed between the stages 22 on which the wafers W are placed and the gas suppliers 4 arranged so as to face the stages 22. In other words, inside the processing container 20, the stages 22 and the gas suppliers 4 are provided for the four processing spaces S1 to S4. FIG. 6 shows the processing spaces S1 and S3. Hereinafter, the processing space S1 will be described as an example.

The stage 22 that also serves as a lower electrode is formed in a flat columnar shape by, for example, metal or aluminum nitride (AlN) in which a metal mesh electrode is embedded. The stage 22 is supported from below by a support member 23. The support member 23 is formed in a cylindrical shape, extends vertically downward, and penetrates a bottom portion 27 of the processing container 20. A lower end portion of the support member 23 is located outside the processing container 20 and is connected to a rotation drive mechanism 600. The support member 23 is rotated by the rotation drive mechanism 600. The stage 22 is configured to be rotatable with the rotation of the support member 23. That is, the stage 22 is configured to be rotatable about its own axis. Further, an adjustment mechanism 700 for adjusting the position (and inclination) of the stage 22 is provided at the lower end portion of the support member 23. The stage 22 is configured to be moved up and down between a processing position and a delivery position via the support member 23 by the adjustment mechanism 700. In FIG. 6, the stage 22 existing at the delivery position is indicated by a solid line, and the stage 22 existing at the processing position is indicated by a broken line. Further, at the delivery position, the end effector 32 is inserted between the stage 22 and the wafer W to receive the wafer W from the lift pins 26. The processing position is a position in which a substrate processing (e.g., a film-forming process) is executed, and the delivery position is a position in which the wafer W is transferred to and from the substrate transfer mechanism (not shown) or the end effector 32.

A heater 24 is embedded in the stage 22. The heater 24 heats each wafer W placed on the stage 22 to, for example, about 60 degrees C. to 600 degrees C. Further, the stage 22 is connected to a ground potential.

Further, the stage 22 is provided with a plurality of (e.g., three) pin through-holes 26a in which lift pins 26 are arranged. The pin through-holes 26a are provided so as to extend from the placement surface (upper surface) of the stage 22 to the back surface (lower surface) opposite to the placement surface. The lift pins 26 are slidably inserted into the respective pin through-holes 26a. Upper ends of the lift pins 26 are suspended on the placement surface side of the pin through-hole 26a. That is, the upper ends of the lift pins 26 have a diameter larger than that of the pin through-hole 26a. A recess having a larger diameter and thickness than the upper ends of the lift pins 26 and capable of accommodating the upper ends of the lift pins 26 is formed at the upper end of each of the pin through-hole 26a. As a result, the upper ends of the lift pins 26 are locked to the stage 22 and are suspended from the placement surface side of the pin through-holes 26a. In addition, the lower ends of the lift pins 26 protrude from the back surface of the stage 22 toward the bottom portion 27 of the processing container 20 and is provided so as to be able to come into contact with an elevating mechanism (not shown).

In a state in which the stage 22 is moved up to the processing position, the upper ends of the lift pins 26 are accommodated in the recesses on the placement surface side of the pin through-holes 26a. When the stage 22 is moved down to the delivery position from this state and the lift pins 26 are moved up by an elevating mechanism (not shown), the upper ends of the lift pins 26 protrude from the placement surface of the stage 22.

The gas supplier 4 is provided in the ceiling portion of the processing container 20 above the stage 22 via a guide member 362 made of an insulating member. The gas supplier 4 has a function as an upper electrode. The gas supplier 4 includes a lid 42, a shower plate 43 having a facing surface provided so as to face the placement surface of the stage 22, and a gas flow chamber 44 formed between the lid 42 and the shower plate 43. A gas supply pipe 51 is connected to the lid 42. Gas discharge holes 45 penetrating the shower plate 43 in the thickness direction are arranged, for example, lengthwise and breadthwise in the shower plate 43. A gas is discharged toward the stage 22 in the form of a shower.

Each gas supplier 4 is connected to a gas supply system 50 via the gas supply pipe 51. The gas supply system 50 includes, for example, a source of a reaction gas (film-forming gas) which is a processing gas, a source of a purge gas, a source of a cleaning gas, pipes, valves V, flow rate adjustment parts M, and the like. The gas supply system 50 includes, for example, a cleaning gas source 53, a reaction gas source 54, a purge gas source 55, valves V1 to V3 provided in the pipes of the respective sources, and flow rate adjustment parts M1 to M3.

The cleaning gas source 53 is connected to a cleaning gas supply path 532 via the flow rate adjustment part M1, the valve V1 and a remote plasma unit (RPU) 531. The cleaning gas supply path 532 is branched into four branch pipes on the downstream side of the RPU 531. The four branch pipes are connected to the gas supply pipes 51, respectively. Valves V11 to V14 are provided in the respective branch pipes on the downstream side of the RPU 531. The corresponding valves V11 to V14 are opened at the time of cleaning. In FIG. 6, only the valves V11 and V14 are shown for the sake of convenience in illustration.

The reaction gas source 54 and the purge gas source 55 are connected to a gas supply path 52 via the flow rate adjustment parts M2 and M3 and the valves V2 and V3, respectively. The gas supply path 52 is connected to the gas supply pipe 51 via a gas supply pipe 510. In FIG. 6, the gas supply path 52 and the gas supply pipe 510 collectively show each supply path and each supply pipe corresponding to each gas supplier 4.

A radio-frequency power source 41 is connected to the shower plate 43 via a matcher 40. The shower plate 43 has a function as an upper electrode facing the stage 22. When radio-frequency power is applied between the shower plate 43 which is the upper electrode and the stage 22 which is the lower electrode, the gas supplied from the shower plate 43 to the processing space S1 (the reaction gas in this example) can be turned into plasma by capacitive coupling.

Subsequently, the exhaust paths from the processing spaces S1 to S4 to the junction exhaust port 205 will be described. As shown in FIGS. 5 and 6, the exhaust paths pass through the respective exhaust paths 361 from the annular flow paths 363 in the respective guide members 362 provided in the upper portion of the processing spaces S1 to S4. The exhaust paths extend to the junction exhaust port 205 via the junction portion at the lower center of the manifold 36 and the hole 351. The exhaust paths 361 are formed to have, for example, a circular cross section.

Around each of the processing spaces S1 to S4, a guide member 362 for exhaust is provided so as to surround each of the processing spaces S1 to S4. The guide member 362 is, for example, an annular body provided so as to surround the area around the stage 22 existing at the processing position with a spacing left from the stage 22. The guide member 362 is configured to form, therein, a flow path 363 having, for example, a rectangular vertical cross section and having an annular shape in a plan view. FIG. 5 schematically shows the processing spaces S1 to S4, the guide members 362, the exhaust paths 361, and the manifold 36.

The guide member 362 forms a slit-shaped slit exhaust port 364 opened toward each of the processing spaces S1 to S4. In this way, the slit exhaust port 364 is formed along the circumferential direction at the side peripheral portion of each of the processing spaces S1 to S4. The exhaust path 361 is connected to the flow path 363, and the processing gas exhausted from the slit exhaust port 364 is allowed to flow toward the junction portion at the lower center of the manifold 36 and the hole 351.

As shown in FIG. 5, the set of the processing spaces S1 and S2 and the set of the processing spaces S3 and S4 are arranged in a 180° rotationally symmetrical relationship around the manifold 36 when viewed from above. As a result, the flow paths of the processing gas from the processing spaces S1 to S4 to the hole 351 via the slit exhaust ports 364, the flow paths 363 of the guide members 362 and the exhaust paths 361 are formed in a 180° rotationally symmetrical relationship around the hole 351.

The hole 351 is connected to an exhaust pipe 61 via a junction exhaust port 205 existing inside a thrust pipe 341 of a dual-axis vacuum seal 34 arranged at the central portion of the processing container 20. The exhaust pipe 61 is connected to a vacuum pump 62 that constitutes a vacuum exhaust mechanism via a valve mechanism 7. One vacuum pump 62 is provided in, for example, one processing container 20. The exhaust pipes on the downstream side of the respective vacuum pumps 62 are joined and connected to, for example, a factory exhaust system.

The valve mechanism 7 opens and closes a flow path for the processing gas formed in the exhaust pipe 61 and includes, for example, a casing 71 and an opening/closing part 72. A first opening 73 connected to the exhaust pipe 61 on the upstream side is formed on the upper surface of the casing 71, and a second opening 74 connected to the exhaust pipe on the downstream side is formed on the side surface of the casing 71.

The opening/closing part 72 includes, for example, an on-off valve 721 formed in a size that closes the first opening 73, and an elevating mechanism 722 provided outside the casing 71 and configured to raise and lower the on-off valve 721 inside the casing 71. The on-off valve 721 is configured to move up and down between a closing position at which the first opening 73 is closed, which is indicated by a one-dot chain line in FIG. 6, and an opening position where the on-off valve 721 is retracted downward from the first and second openings 73 and 74, which is indicated by a solid line in FIG. 6. When the on-off valve 721 is in the closing position, the downstream end of the junction exhaust port 205 is closed and the evacuation of the interior of the processing container 20 is stopped. Further, when the on-off valve 721 is in the opening position, the downstream end of the junction exhaust port 205 is opened and the interior of the processing container 20 is evacuated.

Next, the dual-axis vacuum seal 34 and the thrust nut 35 will be described. The dual-axis vacuum seal 34 includes a thrust pipe 341, bearings 342 and 344, a rotor 343, a main body portion 345, magnetic fluid seals 346 and 347, and a direct drive motor 348.

The thrust pipe 341, which is a non-rotating central shaft, receives a thrust load applied to the upper center of the substrate processing apparatus 2 via the thrust nut 35. That is, the thrust pipe 341 suppresses the deformation of the upper portion of the substrate processing apparatus 2 by receiving the vacuum load applied to the central portion of the substrate processing apparatus 2 when the processing spaces S1 to S4 have a vacuum atmosphere. Further, the thrust pipe 341 has a hollow structure, and the interior thereof is a junction exhaust port 205. The upper surface of the thrust pipe 341 is in contact with the lower surface of the thrust nut 35. Moreover, a gap between the inner surface of the upper portion of the thrust pipe 341 and the outer surface of the recess on the inner peripheral side of the thrust nut 35 is sealed by an O-ring (not shown). In addition, the lower surface of the thrust pipe 341 is fixed to the main body portion 345 by a bolt (not shown).

The outer circumferential surface of the thrust nut 35 has a threaded structure, and the thrust nut 35 is threadedly coupled to the partition wall at the center of the processing container 20. The central portion of the processing container 20 is provided with a manifold 36 at the upper portion thereof. The thrust load is received by the manifold 36, the partition wall at the central portion of the processing container 20, the thrust nut 35, and the thrust pipe 341. A portion of the lower surface of the manifold 36 is in contact with the upper surface of the thrust nut 35.

The bearing 342 is a radial bearing that holds the rotor 343 on the thrust pipe 341 side. The bearing 344 is a radial bearing that holds the rotor 343 on the main body portion 345 side. The rotor 343 is arranged concentrically with the thrust pipe 341 and is a rotation shaft at the center of the rotary arm 3. Further, a base member 33 is connected to the rotor 343. The rotation of the rotor 343 causes the rotary arm 3, i.e., the end effector 32 and the base member 33 to rotate.

The main body portion 345 accommodates the bearings 342 and 344, the rotor 343, the magnetic fluid seals 346 and 347, and the direct drive motor 348 therein. The magnetic fluid seals 346 and 347 are arranged on the inner peripheral side and the outer peripheral side of the rotor 343 to seal the processing spaces S1 to S4 with respect to the outside. The direct drive motor 348 is an example of a rotation mechanism and is connected to the rotor 343. The direct drive motor 348 drives the rotor 343 to thereby rotate the rotary arm 3. In addition, the main body portion 345 is fixed to the bottom portion 27 (bottom surface) of the processing container 20 by bolts (not shown). The thrust load applied to the thrust pipe 341 is received by the processing container 20 via the main body portion 345.

In other words, the rotor 343 is an example of a hollow rotary cylinder and corresponds to an outer cylinder of the dual-axis vacuum seal 34 which is an example of a coaxial magnetic fluid seal. Further, the rotor 343 is located at a position equidistant from the respective processing spaces S1 to S4. On the other hand, the thrust pipe 341 is located in a hollow portion on the inner peripheral side of the rotor 343. The junction exhaust port 205 inside the thrust pipe 341 is an example of an exhaust path and corresponds to the inner cylinder of the dual-axis vacuum seal 34. Further, the upper surface of the thrust pipe 341 is fixed to the partition wall at the center of the processing container 20, i.e., the upper wall of the processing container 20 via the thrust nut 35. That is, the thrust pipe 341 supports the manifold 36 with respect to the bottom wall (bottom portion 27) of the processing container 20 via the partition wall at the center of the processing container 20 and the thrust nut 35.

As described above, in the dual-axis vacuum seal 34, the thrust pipe 341 which is a non-rotating central axis as a first axis plays the role of a gas exhaust pipe while supporting the load on the upper portion of the processing container 20, and the rotor 343 as a second axis serves to rotate the rotary arm 3.

The substrate processing apparatus 2 includes a controller 8. The controller 8 is a computer including, for example, a processor, a memory part, an input device, a display device, and the like. The controller 8 controls each part of the substrate processing apparatus 2. The controller 8 enables an operator to use the input device to perform a command input operation or the like to manage the substrate processing apparatus 2. Further, the controller 8 may cause the display device to visually display the operating status of the substrate processing apparatus 2. Further, the memory part of the controller 8 stores a control program for controlling various processes to be executed by the substrate processing apparatus 2 through the use of the processor, recipe data, and the like. The processor of the controller 8 executes the control program and controls each part of the substrate processing apparatus 2 according to the recipe data, so that a desired substrate processing process or a desired measurement process can be executed by the substrate processing apparatus 2.

### [Configuration of Back Surface of End Effector]

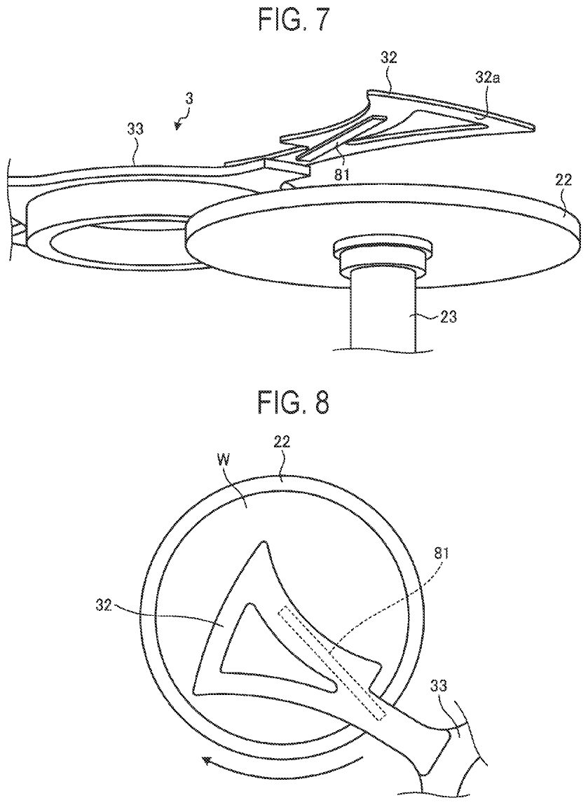

Further, the substrate processing apparatus 2 may rotate the rotary arm 3 inside the processing container 20 to bring the sensor close to the stage 22 or the wafer W placed on the stage 22 to perform measurements on the stage 22 or the wafer W. In this case, as shown in FIGS. 6 and 7, a sensor 81 is provided on a back surface 32a of the end effector 32 of the rotary arm 3 of the substrate processing apparatus 2 opposite to the substrate holding surface thereof. FIG. 7 is a perspective view showing an example of a configuration in which the rotary arm 3 shown in FIG. 6 is viewed from the back surface 32a side of the end effector 32. The sensor 81 can perform measurements on the stage 22 or the wafer W placed on the stage 22 at a position facing the stage 22 or the wafer W placed on the stage 22. Parameters that can be measured on the stage 22 by the sensor 81 include a temperature, a surface roughness, the number of particles, and the like. Further, the parameters that can be measured on the wafer W by the sensor 81 include a temperature, a film thickness, a film quality, a surface roughness, the number of particles, and the like. The sensor 81 may be an image sensor capable of capturing an image of an object.

When starting measurements, the controller 8 operates the direct drive motor 348 (see FIG. 6) to rotate the rotary arm 3 so that the sensor 81 can move to a position where the sensor 81 faces the stage 22 or the wafer W placed on the stage 22 inside the processing container 20. Then, the controller 8 causes the sensor 81 to perform measurements on the stage 22 or the wafer W placed on the stage 22 at a position where the sensor 81 faces the stage 22 or the wafer W. For example, when the wafer W is placed on each stage 22 located at the delivery position in the transfer space T, the controller 8 rotates the rotary arm 3 clockwise by about 30° from the standby position to move the sensor 81 to a position where the sensor 81 faces the wafer W to measure the wafer W.

In this way, the substrate processing apparatus 2 rotates the rotary arm 3 so as to move the sensor 81 to the position where the sensor 81 faces the stage 22 or the wafer W placed on the stage 22 inside the processing container 20, and causes the sensor 81 to perform measurements on the stage 22 or the wafer W at the respective position. As a result, the substrate processing apparatus 2 can perform various measurements on the stage 22 or the wafer W inside the processing container 20 without transferring the stage 22 or the wafer W to the outside of the processing container 20.

FIG. 8 is a diagram showing an example of the operation of the substrate processing apparatus 2. FIG. 8 shows a state in which the sensor 81 is moved to a position facing the wafer W placed on the stage 22 by the rotation of the rotary arm 3. The sensor 81 is provided in at least a region of the back surface 32a of the end effector 32 that can face a line segment extending from the center of the stage 22 or the wafer W to the outer periphery thereof when the back surface 32a faces the stage 22 or the wafer W. If the stage 22 is rotatable, the sensor 81 may be provided in a region that can face a curve connecting the center of the stage 22 or the wafer W to the outer periphery thereof. Even in such a case, it can be said that the sensor 81 is provided in a region that can face the line segment extending from the center of the stage 22 or the wafer W to the outer periphery thereof. In the example of FIG. 8, the sensor 81 is provided in a rectangular region that extends along a line segment extending from the center of the stage 22 or the wafer W to the outer periphery thereof.

The stage 22 is configured to be rotatable with the driving of the rotation drive mechanism 600 (see FIG. 6). After moving to the position facing the wafer W, the sensor 81 performs measurements on the wafer W in a state in which the stage 22 is rotating as shown in FIG. 8. As a result, the substrate processing apparatus 2 can perform various measurements on the entire surface of the wafer W.

The sensor 81 is provided on the back surface 32a of each of the four end effectors 32 whose number is the same as the number of the processing spaces S1 to S4. As a result, the substrate processing apparatus 2 can simultaneously perform various measurements on the stages 22 or the wafers W in the respective processing spaces S1 to S4. The substrate processing apparatus 2 may rotate the rotary arm 3 so that the sensor 81 on the back surface 32a of each of the four end effectors 32 circulates through the four processing spaces S1 to S4. The four measurement values measured by the sensor 81 for the respective processing spaces S1 to S4 may be averaged.

The sensor 81 does not necessarily have to be provided on the back surfaces 32a of all the end effectors 32. For example, the sensor 81 may be provided on the back surface 32a of one of the four end effectors 32. In this case, the substrate processing apparatus 2 rotates the rotary arm 3 so that one sensor 81 on the back surface 32a of one end effector 32 can sequentially move to the positions facing the stage 22 or the wafer W in the respective processing spaces S1 to S4. As a result, the substrate processing apparatus 2 can measure the stages 22 or the wafers W in the respective processing spaces S1 to S4 by using a common sensor 81. Therefore, it is possible to reduce the measurement error between the processing spaces S1 to S4 due to the error between the sensors.

Further, during the period of measurements performed by the sensor 81, the substrate processing apparatus 2 may operate the adjustment mechanism 700 (see FIG. 6) and may move the stage 22 or the wafer W to a focus position of the sensor 81 according to the adjustment performed by the adjustment mechanism 700. For example, the substrate processing apparatus 2 may rotate the rotary arm 3 so that the sensor 81 can be moved to the position facing the stage 22 or the wafer W, and then may control the adjustment mechanism 700 to move the stage 22 upward so as to approach the sensor 81. As a result, the substrate processing apparatus 2 can perform more precise measurements on the stage 22 or the wafer W.

### [Modification]

The above embodiment discloses a case where the sensor 81 is provided in the rectangular region of the back surface 32a of each of the end effectors 32 of the rotary arm 3. However, a sensor 82 which is a spot sensor smaller than the sensor 81 may be provided on the back surface 32a. Such a form will be described as a modification.

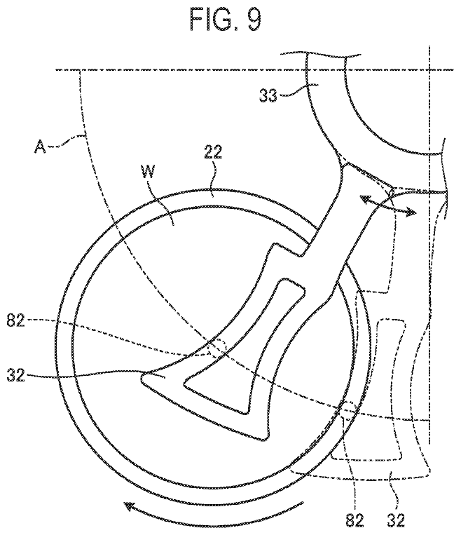

FIG. 9 is a diagram for explaining an example of the sensor 82 according to the modification. The sensor 82, which is a spot sensor smaller than the sensor 81 of the embodiment, is provided on the back surface 32a of each of the end effectors 32 of the rotary arm 3 shown in FIG. 9 opposite to the substrate holding surface. Parameters that can be measured on the stage 22 or the wafer W by the sensor 82 are the same as the parameters that can be measured on the stage 22 or the wafer W by the sensor 81.

The sensor 82 is provided at a local position on the back surface 32a of the end effector 32, which is set on an arc A centered on the rotation axis of the rotary arm 3 and passing through the center of the stage 22.

When starting the measurements, the controller 8 operates the direct drive motor 348 (see FIG. 6) to rotate the rotary arm 3 so that the sensor 82 can be moved to a position facing the stage 22 or the wafer W placed on the stage 22 inside the processing container 20. Further, the controller 8 operates the rotation drive mechanism 600 (see FIG. 6) to rotate the stage 22. Subsequently, during the period of measurement performed by the sensor 82, the controller 8 operates the direct drive motor 348 while the stage 22 is rotating, and rotates the rotary arm 3 so that the sensor 82 can move between the center and the outer periphery of the stage 22 along the arc A. In FIG. 9, the rotary arm 3 when the sensor 82 is located at the center of the stage 22 is indicated by a solid line, and the rotary arm 3 when the sensor 82 is located on the outer periphery of the stage 22 is indicated by a two-dot chain line. As a result, the substrate processing apparatus 2 can perform various measurements on the entire surface of the stage 22 or the entire surface of the wafer W.

In the above-described embodiment, the direct drive motor 348 is used as the driving method of the rotor 343 in the dual-axis vacuum seal 34. However, the present disclosure is not limited thereto. For example, the rotor 343 may be provided with a pulley and may be driven by a timing belt from a motor provided outside the dual-axis vacuum seal 34. Further, gear driving may be performed by engagement of a gear provided in the rotor 343, which is the outer cylinder, with a gear of the motor provided outside. Similarly, in a method of driving a first rotary cylinder and a second rotary cylinder in a triple-axis vacuum seal, it may be possible to use any of the driving by the direct drive motor, the driving by the timing belt, and the driving by the gears.

As described above, according to the present embodiment, the substrate processing apparatus 2 includes the processing container 20, the substrate stage (e.g., the stage 22), the rotary arm 3, the sensor (e.g., the sensors 81 and 82), and the rotation mechanism (e.g., the direct drive motor 348). The plurality of processing spaces S1 to S4 is formed inside the processing container 20. The substrate stage is arranged in each of the plurality of processing spaces S1 to S4. The rotary arm 3 includes the end effector 32 capable of holding the substrate (e.g., the wafer W). The rotation axis is located at a position equidistant from the respective processing spaces S1 to S4. The sensor is provided on the back surface 32a of the end effector 32 of the rotary arm 3 opposite to the substrate holding surface. The rotation mechanism rotates the rotary arm 3 so that the sensor can be moved to the position facing the substrate stage or the substrate placed on the substrate stage inside the processing container 20. As a result, various measurements can be performed on the substrate stage or the substrate placed on the substrate stage inside the processing container 20.

Further, according to the present embodiment, the substrate stage may be configured to be rotatable. The sensor may be moved to the position facing the substrate stage or the substrate and then may perform measurements on the substrate stage or the substrate while the substrate stage is rotating. As a result, various measurements can be performed on the entire surface of the substrate stage or the entire surface of the substrate.

Further, according to the present embodiment, the sensor (e.g., the sensor 81) may be provided in at least a region of the back surface 32a of the end effector 32 that can face a line segment extending from the center of the substrate stage or the substrate to the outer periphery thereof when the back surface 32a faces the substrate stage or the substrate. As a result, various measurements can be performed on the entire surface of the substrate stage or the entire surface of the substrate.

Further, according to the present embodiment, the sensor (e.g., the sensor 82) may be provided at a local position on the back surface 32a of the end effector 32, which is set on an arc A centered on the rotation axis of the rotary arm 3 and passing through the center of the substrate stage. As a result, even when the sensor 82, which is a small spot sensor, is used, various measurements can be performed on the entire surface of the substrate stage or the entire surface of the substrate.

Further, according to the present embodiment, the substrate processing apparatus 2 may further include the adjustment mechanism 700 configured to adjust the position of the substrate stage. The substrate stage or the substrate may be movable to a focus position of the sensor in response to the adjustment performed by the adjustment mechanism 700. As a result, more precise measurement can be performed on the substrate stage or the substrate.

Further, according to the present embodiment, the rotary arm 3 may include the plurality of end effectors 32 whose number is the same as the number of the processing spaces S1 to S4. The sensor may be provided on the back surface 32a of each of the plurality of end effectors 32. As a result, various measurements on the substrate stages or the substrates in the respective processing spaces S1 to S4 can be performed at the same time.

Further, according to the present embodiment, the method of controlling the substrate processing apparatus is a method of controlling the substrate processing apparatus 2 including the processing container 20, the substrate stage, the rotary arm 3, the sensor, and the rotation mechanism. The method of controlling the substrate processing apparatus includes a step of rotating and a step of performing measurement. In the step of rotating, the rotary arm 3 is rotated by the rotation mechanism so that the sensor is moved to a position facing the substrate stage or the substrate placed on the substrate stage inside the processing container 20. In the step of performing measurement, the measurement is performed on the substrate stage or the substrate by the sensor at the position facing the substrate stage or the substrate. As a result, various measurements can be performed on the substrate stage or the substrate placed on the substrate stage inside the processing container 20.

It should be noted that the embodiments disclosed herein are exemplary in all respects and not limitative. The above embodiments may be omitted, replaced or modified in various forms without departing from the scope of the appended claims and the gist thereof.

For example, in the above embodiments, there has been described the example in which the substrate processing apparatus 2 is an apparatus that performs a plasma CVD process as a substrate processing process. However, the techniques disclosed herein may be applied to any apparatus that performs other substrate processing processes such as plasma etching, and the like.

According to the present disclosure in some embodiments, it is possible to perform various measurements on a substrate stage or a substrate placed on the substrate stage inside a processing container.

While certain embodiments have been described, these embodiments have been presented by way of example only and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing container having a plurality of processing spaces formed therein;
a substrate stage arranged in each of the plurality of processing spaces;
a rotary arm including at least one end effector capable of holding a substrate and having a rotation axis located at a position equidistant from the plurality of processing spaces;
a sensor provided on a back surface of the at least one end effector of the rotary arm, which is opposite to a substrate holding surface of the at least one end effector; and
a rotation mechanism configured to rotate the rotary arm so that the sensor is moved to a position facing the substrate stage or the substrate placed on the substrate stage inside the processing container.

2. The substrate processing apparatus of claim 1, wherein the substrate stage is configured to be rotatable, and
the sensor is configured to move to a position facing the substrate stage or the substrate and subsequently, perform measurement on the substrate stage or the substrate while the substrate stage is rotating.

3. The substrate processing apparatus of claim 2, wherein the sensor is provided in at least a region of the back surface of the at least one end effector that faces a line segment extending from a center of the substrate stage or the substrate to an outer periphery thereof when the back surface faces the substrate stage or the substrate.

4. The substrate processing apparatus of claim 3, further comprising:
an adjustment mechanism configured to adjust a position of the substrate stage,
wherein the substrate stage or the substrate is movable to a focus position of the sensor in response to the adjustment performed by the adjustment mechanism.

5. The substrate processing apparatus of claim 4, wherein the at least one end effectors of the rotary arm includes a plurality of end effectors whose number is the same as the number of the plurality of processing spaces, and the sensor is provided on the back surface of each of the plurality of end effectors.

6. The substrate processing apparatus of claim 2, wherein the sensor is provided at a local position on the back surface of the at least one end effector, which is set on an arc centered on the rotation axis of the rotary arm and passing through the center of the substrate stage, and
the rotation mechanism is configured to rotate the rotary arm so that the sensor is moved between the center and the outer periphery of the substrate stage along the arc while the substrate stage is rotating during a period of the measurement performed by the sensor.

7. The substrate processing apparatus of claim 6, further comprising:
an adjustment mechanism configured to adjust a position of the substrate stage,
wherein the substrate stage or the substrate is movable to a focus position of the sensor in response to the adjustment performed by the adjustment mechanism.

8. The substrate processing apparatus of claim 7, wherein the at least one end effectors of the rotary arm includes a plurality of end effectors whose number is the same as the number of the plurality of processing spaces, and the sensor is provided on the back surface of each of the plurality of end effectors.

9. The substrate processing apparatus of claim 1, further comprising:
an adjustment mechanism configured to adjust a position of the substrate stage,
wherein the substrate stage or the substrate is movable to a focus position of the sensor in response to the adjustment performed by the adjustment mechanism.

10. The substrate processing apparatus of claim 1, wherein the at least one end effectors of the rotary arm includes a plurality of end effectors whose number is the same as the number of the plurality of processing spaces, and the sensor is provided on the back surface of each of the plurality of end effectors.

11. A method of controlling a substrate processing apparatus that includes a processing container having a plurality of processing spaces formed therein, a substrate stage arranged in each of the plurality of processing spaces, a rotary arm including at least one end effector capable of holding a substrate and having a rotation axis located at a position equidistant from the plurality of processing spaces, a sensor provided on a back surface of the at least one end effector of the rotary arm, which is opposite to a substrate holding surface of the at least one end effector, and a rotation mechanism configured to rotate the rotary arm, the method comprising:
rotating, by the rotation mechanism, the rotary arm so that the sensor is moved to a position facing the substrate stage or the substrate placed on the substrate stage inside the processing container; and
performing, by the sensor, measurement on the substrate stage or the substrate at the position facing the substrate stage or the substrate.
